(19) United States
(12) Patent Application Publication
(10) Pub. No.: US 2019/0164959 A1
(43) Pub. Date: May 30, 2019

(54) ON-CHIP CONTROL LOGIC FOR QUBITS

(71) Applicant: Intel Corporation, Santa Clara, CA (US)

(72) Inventors: Nicole K. Thomas, Portland, OR (US); Ravi Pillarisetty, Portland, OR (US); Jeanette M. Roberts, North Plains, OR (US); Hubert C. George, Portland, OR (US); James S. Clarke, Portland, OR (US)

(73) Assignee: Intel Corporation, Santa Clara, CA (US)

(21) Appl. No.: 16/320,773

(22) PCT Filed: Sep. 29, 2016
(86) PCT No.: PCT/US2016/054296

§ 371 Date: Jan. 25, 2019

(51) Int. Cl. H01L 27/06; G06N 10/00; H01L 27/18; H01L 29/66; H01L 29/76; H01L 39/22; H01L 29/12; H01L 29/778; H01L 39/24

(52) U.S. Cl. CPC H01L 27/0629; G06N 10/00; H01L 27/18; H01L 29/66977; B82Y 10/00; H01L 39/223; H01L 29/127; H01L 29/778; H01L 39/2493; H01L 29/7613

(57) ABSTRACT

Described herein are quantum integrated circuit (IC) assemblies that include quantum circuit components comprising a plurality of qubits and control logic coupled to the quantum circuit components and configured to control operation of those components, where the quantum circuit component(s) and the control logic are provided on a single die. By implementing control logic on the same die as the quantum circuit component(s), more functionality can be provided on-chip, thus integrating more of signal chain on-chip. Integration can greatly reduce complexity and lower the cost of quantum computing devices, reduce interfacing bandwidth, and provide an approach that can be efficiently used in large scale manufacturing. Methods for fabricating such assemblies are also disclosed.

### CROSS-REFERENCE TO RELATED APPLICATION

This application is a national stage application under 35 U.S.C. § 371 of PCT International Application Serial No. PCT/US2016/054296, filed on Sep. 29, 2016 and entitled “ON-CHIP CONTROL LOGIC FOR QUBITS,” which is hereby incorporated by reference herein in its entirety.

### TECHNICAL FIELD

This disclosure relates generally to the field of quantum computing, and more specifically, to the integration of control logic with quantum circuits.

### BACKGROUND

Quantum computing refers to the field of research related to computation systems that use quantum mechanical phenomena to manipulate data. These quantum mechanical phenomena, such as superposition (in which a quantum variable can simultaneously exist in multiple different states) and entanglement (in which multiple quantum variables have related states irrespective of the distance between them in space or time), do not have analogs in the world of classical computing, and thus cannot be implemented with classical computing devices.

### BRIEF DESCRIPTION OF THE DRAWINGS

To provide a more complete understanding of the present disclosure and features and advantages thereof, reference is made to the following description, taken in conjunction with the accompanying figures, wherein like reference numerals represent like parts, in which:

FIGS. 1-3 are cross-sectional views of an exemplary device implementing quantum dot qubits, according to some embodiments of the present disclosure.

FIGS. 4-6 are cross-sectional views of various examples of quantum well stacks that may be used in a quantum dot device, according to some embodiments of the present disclosure.

FIGS. 7-13 illustrate example base/fin arrangements that may be used in a quantum dot device, according to some embodiments of the present disclosure.

FIG. 14 provides a schematic illustration of an exemplary device implementing superconducting qubits, according to some embodiments of the present disclosure.

FIG. 15 provides a schematic illustration of an exemplary physical layout of a device implementing superconducting qubits, according to some embodiments of the present disclosure.

FIG. 16 provides a schematic illustration of control logic integrated with a quantum circuit component that includes one or more qubits, according to some embodiments of the present disclosure.

FIG. 17 provides a flow chart of an exemplary method for fabricating control logic integrated with a quantum circuit component, according to some embodiments of the present disclosure.

FIG. 18 provides a schematic illustration of an exemplary quantum computing device that may include control logic integrated with any of quantum circuit components as described herein, according to some embodiments of the present disclosure.

### DETAILED DESCRIPTION

### Overview

As previously described herein, quantum computing, or quantum information processing, refers to the field of research related to computation systems that use quantum-mechanical phenomena to manipulate data. One example of quantum-mechanical phenomena is the principle of quantum superposition, which asserts that any two or more quantum states can be added together, i.e. superposed, to produce another valid quantum state, and that any quantum state can be represented as a sum of two or more other distinct states. Quantum entanglement is another example of quantum-mechanical phenomena. Entanglement refers to groups of particles being generated or interacting in such a way that the state of one particle becomes intertwined with that of the others. Furthermore, the quantum state of each particle cannot be described independently. Instead, the quantum state is given for the group of entangled particles as a whole. Yet another example of quantum-mechanical phenomena is sometimes described as a “collapse” because it asserts that when we observe (measure) particles, we unavoidably change their properties in that, once observed, the particles cease to be in a state of superposition or entanglement (i.e. by trying to ascertain anything about the particles, we collapse their state).

Put simply, superposition postulates that a given particle can be simultaneously in two states, entanglement postulates that two particles can be related in that they are able to instantly coordinate their states irrespective of the distance between them in space and time, and collapse postulates that when one observes a particle, one unavoidably changes the state of the particle and its' entanglement with other particles. These unique phenomena make manipulation of data in quantum computers significantly different from that of classical computers (i.e. computers that use phenomena of classical physics). Classical computers encode data into binary values, commonly referred to as bits. At any given time, a bit is always in only one of two states—it is either 0 or 1. Quantum computers use so-called quantum bits, referred to as qubits (both terms “bits” and “qubits” often interchangeably refer to the values that they hold as well as to the actual devices that store the values). Similar to a bit of a classical computer, at any given time, a qubit can be either 0 or 1. However, in contrast to a bit of a classical computer, a qubit can also be 0 and 1 at the same time, which is a result of superposition of quantum states. Entanglement also contributes to the unique nature of qubits in that input data to a quantum processor can be spread out among entangled qubits, allowing manipulation of that data to be spread out as well: providing input data to one qubit results in that data being shared to other qubits with which the first qubit is entangled.

Compared to well-established and thoroughly researched classical computers, quantum computing is still in its infancy, with the highest number of qubits in a solid-state quantum processor currently being about 10. One of the main challenges resides in protecting qubits from decoherence so that they can stay in their information-holding states long enough to perform the necessary calculations and read out the results.

Qubits are often operated at cryogenic temperatures, typically just a few degrees Kelvin or even just a few milliKelvin above absolute zero, because at cryogenic temperatures thermal energy is low enough to not cause spurious excitations, which is thought to help minimize qubit decoherence. Operation of the qubits is controlled with control logic. The control logic is typically “external” in a sense that, while qubits are kept at cryogenic temperatures, the control logic is provided on a separate device or a chip that is kept at higher temperatures, with wires connecting the control logic and the qubits. While this may be suitable for implementing just a few qubits, such an approach will face significant challenges with quantum circuit components that include larger number of qubits. In addition, such an approach is not suitable for large-scale manufacturing of quantum computing devices.

Embodiments of the present disclosure provide quantum integrated circuit (IC) assemblies that include quantum circuit components comprising a plurality of qubits and control logic coupled to the quantum circuit components and configured to control operation of those components, where the quantum circuit component(s) and the control logic are provided on a single die. By implementing control logic on the same die as the quantum circuit component(s), more functionality can be provided on-chip, thus integrating more of signal chain on-chip. Integration can greatly reduce complexity and lower the cost of quantum computing devices, reduce interfacing bandwidth, and provide an approach that can be efficiently used in large-scale manufacturing. Methods for fabricating such assemblies are also disclosed.

For the purposes of the present disclosure, the terms such as “upper,” “lower,” “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

The phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale.

As used herein, terms indicating what may be considered an idealized behavior, such as e.g. “superconducting” or “lossless”, are intended to cover functionality that may not be exactly ideal but is within acceptable margins for a given application. For example, a certain level of loss, either in terms of non-zero electrical resistance or non-zero amount of spurious two-level systems (TLS's) may be acceptable such that the resulting materials and structures may still be referred to by these “idealized” terms. Specific values associated with an acceptable level of loss are expected to change over time as fabrication precision will improve and as fault-tolerant schemes may become more tolerant of higher losses, all of which are within the scope of the present disclosure.

Furthermore, while the present disclosure may include references to microwave signals, this is done only because current qubits are designed to work with such signals because the energy in the microwave range is higher than thermal excitations at the temperature that qubits are operated at. In addition, techniques for the control and measurement of microwaves are well known. For these reasons, typical frequencies of qubits are in 5-10 gigahertz (GHz) range, in order to be higher than thermal excitations, but low enough for ease of microwave engineering. However, advantageously, because excitation energy of qubits is controlled by the circuit elements, qubits can be designed to have any frequency. Therefore, in general, qubits could be designed to operate with signals in other ranges of electromagnetic spectrum and embodiments of the present disclosure could be modified accordingly. All of these alternative implementations are within the scope of the present disclosure.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Furthermore, in the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure. However, the order of description should not be construed to imply that these operations are necessarily order dependent. In particular, these operations need not be performed in the order of presentation. Operations described may be performed in a different order from the described embodiment(s). Various additional operations may be performed, and/or described operations may be omitted in additional embodiments.

Integrated Control Logic Used with Various Types of Qubits

The ability to manipulate and read out quantum states, making quantum-mechanical phenomena visible and traceable, and the ability to deal with and improve on the fragility of quantum states of a qubit present unique challenges not found in classical computers. These challenges explain why so many current efforts of the industry and the academics continue to focus on a search for new and improved physical systems whose functionality could approach that expected of theoretically designed qubits. Physical systems for implementing qubits that have been explored until now include e.g. quantum dot devices, superconducting devices, single trapped ion devices, photon polarization devices, etc. To indicate that these devices implement qubits, sometimes these devices are referred to as qubits, e.g. quantum dot qubits, superconducting qubits, etc.

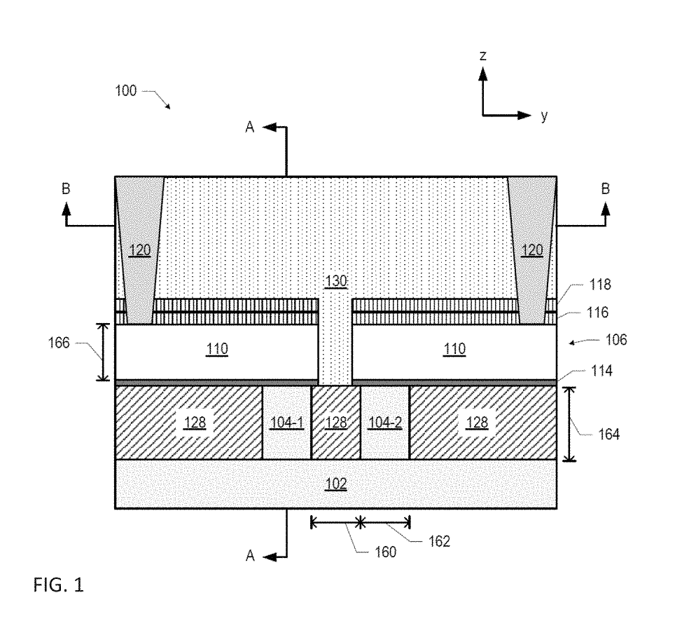

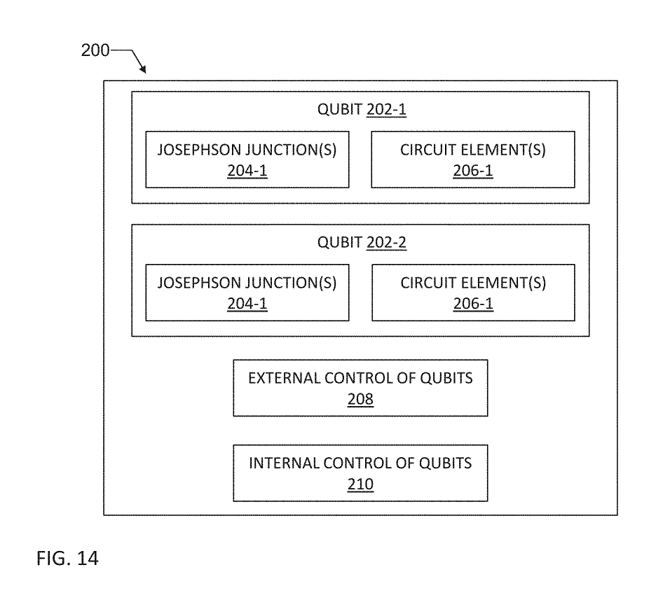

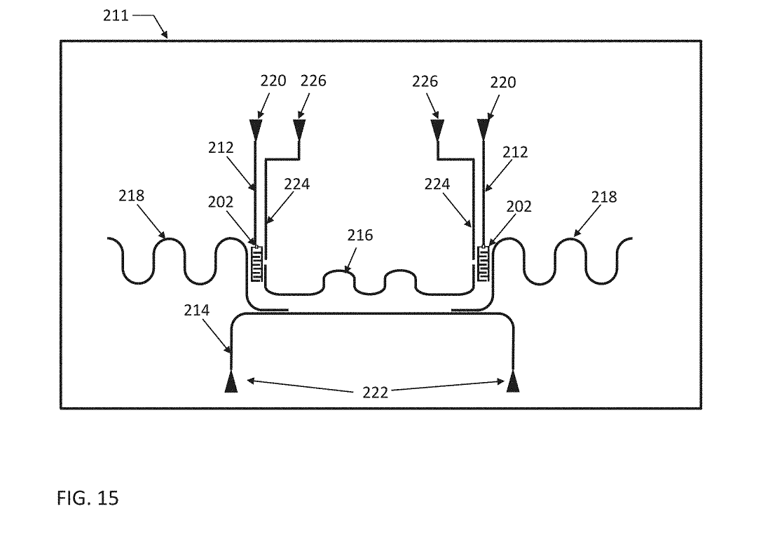

The type of qubits used in a quantum circuit component would affect what kind of control an on-chip control logic described herein would be configured to provide. Below, two exemplary quantum circuit components are described—one incorporating quantum dot qubits (FIGS. 1-13) and one incorporating superconducting qubits (FIGS. 14-15). However, integration of control logic on the same die with a quantum circuit component, as described herein, is applicable to quantum circuit components that include any type of qubits, all of which are within the scope of the present disclosure.

Exemplary Quantum Circuit Components with Quantum Dot Qubits

Quantum dot devices may enable the formation of quantum dots to serve as quantum bits (i.e. as qubits) in a quantum computing device. One type of quantum dot devices includes devices having a base, a fin extending away from the base, where the fin includes a quantum well layer, and one or more gates disposed on the fin. A quantum dot formed in such a device may be constrained in the x-direction by the one or more gates, in the y-direction by the fin, and in the z-direction by the quantum well layer, as discussed in detail herein. Unlike previous approaches to quantum dot formation and manipulation, quantum dot devices with fins provide strong spatial localization of the quantum dots (and therefore good control over quantum dot interactions and manipulation), good scalability in the number of quantum dots included in the device, and/or design flexibility in making electrical connections to the quantum dot devices to integrate the quantum dot devices in larger computing devices. Therefore, this is the type of quantum dot device that is described as a first exemplary quantum circuit component that may be integrated with on-chip control logic according to embodiments of the present disclosure.

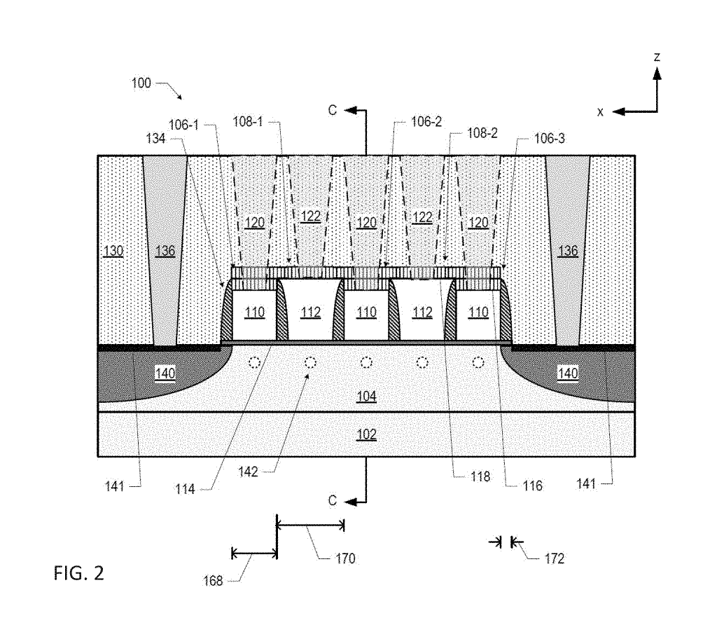

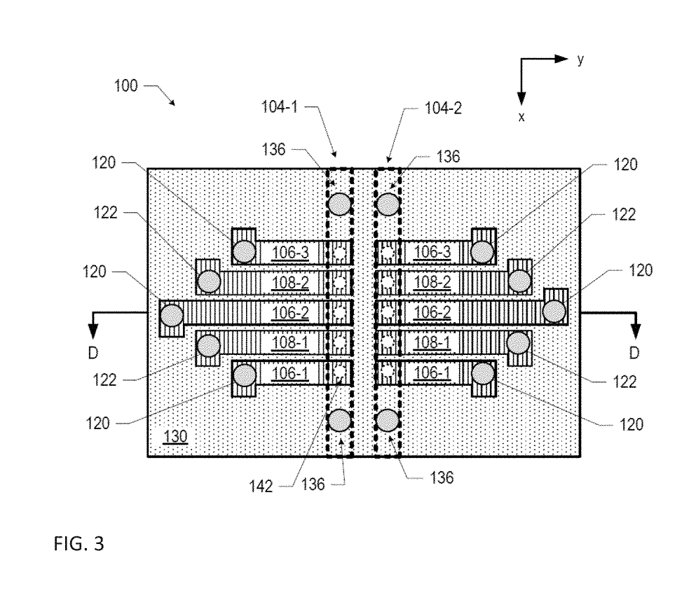

FIGS. 1-3 are cross-sectional views of an exemplary quantum dot device 100 implementing quantum dot qubits, in accordance with various embodiments. In particular, FIG. 2 illustrates the quantum dot device 100 taken along the section A-A of FIG. 1 (while FIG. 1 illustrates the quantum dot device 100 taken along the section C-C of FIG. 2), and FIG. 3 illustrates the quantum dot device 100 taken along the section B-B of FIG. 1 (while FIG. 1 illustrates a quantum dot device 100 taken along the section D-D of FIG. 3). Although FIG. 1 indicates that the cross-section illustrated in FIG. 2 is taken through the fin 104-1, an analogous cross section taken through the fin 104-2 may be identical, and thus the discussion of FIGS. 1-3 refers generally to the “fin 104.”

A quantum circuit component integrated on-chip with control logic as described herein may include one or more of the quantum dot devices 100.

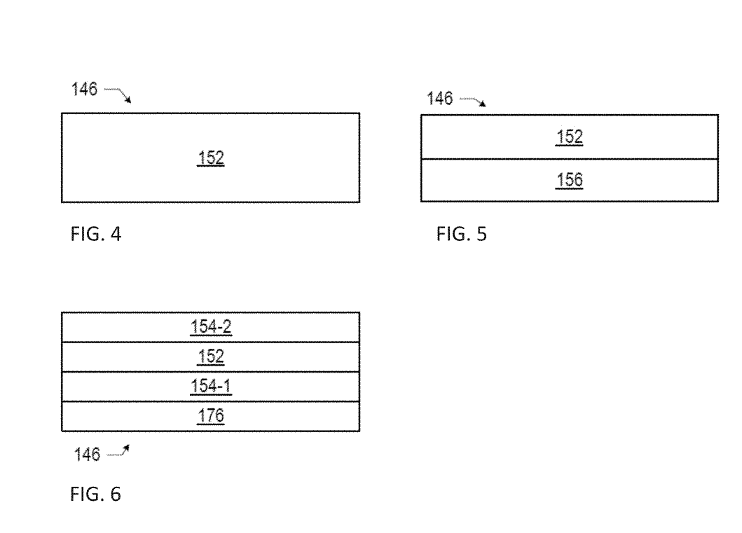

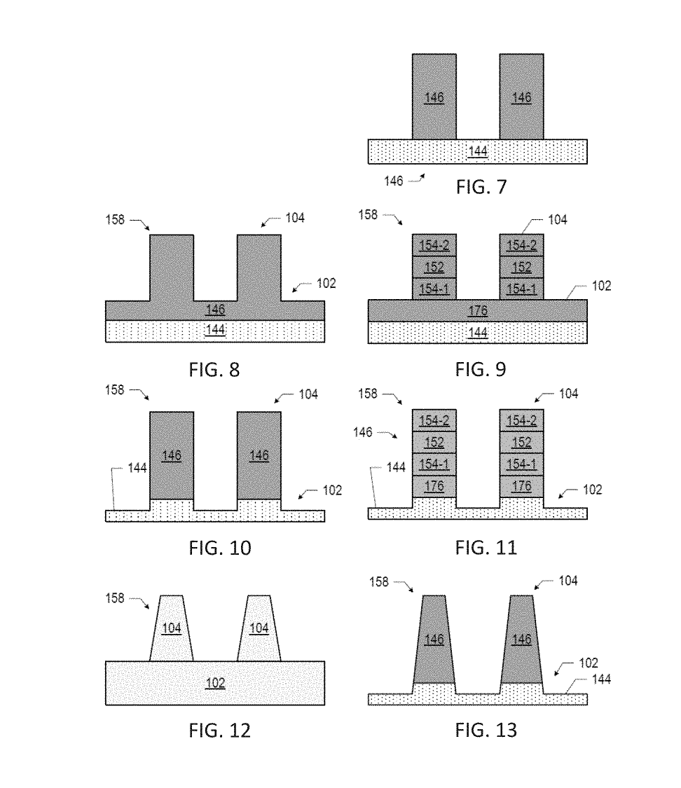

As shown in FIGS. 1-3, the quantum dot device 100 may include a base 102 and multiple fins 104 extending away from the base 102. The base 102 and the fins 104 may include a semiconductor substrate and a quantum well stack (not shown in FIGS. 1-3, but discussed below with reference to the semiconductor substrate 144 and the quantum well stack 146), distributed in any of a number of ways between the base 102 and the fins 104. The base 102 may include at least some of the semiconductor substrate, and the fins 104 may each include a quantum well layer of the quantum well stack (discussed below with reference to the quantum well layer 152 of FIGS. 4-6). Examples of base/fin arrangements are discussed below with reference to the base fin arrangements 158 of FIGS. 7-13.

Although only two fins, 104-1 and 104-2, are shown in FIGS. 1-3, this is simply for ease of illustration, and more than two fins 104 may be included in the quantum dot device 100. In some embodiments, the total number of fins 104 included in the quantum dot device 100 is an even number, with the fins 104 organized into pairs including one active fin 104 and one read fin 104, as discussed in detail below. When the quantum dot device 100 includes more than two fins 104, the fins 104 may be arranged in pairs in a line (e.g., 2N fins total may be arranged in a 1×2N line, or a 2×N line) or in pairs in a larger array (e.g., 2N fins total may be arranged as a 4×N/2 array, a 6×N/3 array, etc.). The discussion herein will largely focus on a single pair of fins 104 for ease of illustration, but all the teachings of the present disclosure apply to quantum dot devices 100 with more fins 104.

As noted above, each of the fins 104 may include a quantum well layer (not shown in FIGS. 1-3, but discussed below with reference to the quantum well layer 152). The quantum well layer included in the fins 104 may be arranged normal to the z-direction, and may provide a layer in which a two-dimensional electron gas (2DEG) may form to enable the generation of a quantum dot during operation of the quantum dot device 100, as discussed in further detail below. The quantum well layer itself may provide a geometric constraint on the z-location of quantum dots in the fins 104, and the limited extent of the fins 104 (and therefore the quantum well layer) in the y-direction may provide a geometric constraint on the y-location of quantum dots in the fins 104. To control the x-location of quantum dots in the fins 104, voltages may be applied to gates disposed on the fins 104 to adjust the energy profile along the fins 104 in the x-direction and thereby constrain the x-location of quantum dots within quantum wells (discussed in detail below with reference to the gates 106/108). The dimensions of the fins 104 may take any suitable values. For example, in some embodiments, the fins 104 may each have a width 162 between 10 and 30 nanometers. In some embodiments, the fins 104 may each have a height 164 between 200 and 400 nanometers (e.g., between 250 and 350 nanometers, or equal to 300 nanometers).

The fins 104 may be arranged in parallel, as illustrated in FIGS. 1 and 3, and may be spaced apart by an insulating material 128, which may be disposed on opposite faces of the fins 104. The insulating material 128 may be a dielectric material, such as silicon oxide. For example, in some embodiments, the fins 104 may be spaced apart by a distance 160 between 100 and 250 microns.

Multiple gates may be disposed on each of the fins 104. In the embodiment illustrated in FIG. 2, three gates 106 and two gates 108 are shown as distributed on the top of the fin 104. This particular number of gates is simply illustrative, and any suitable number of gates may be used. Additionally, multiple groups of gates like the gates illustrated in FIG. 2 may be disposed on the fin 104.

As shown in FIG. 2, the gate 108-1 may be disposed between the gates 106-1 and 106-2, and the gate 108-2 may be disposed between the gates 106-2 and 106-3. Each of the gates 106/108 may include a gate dielectric 114. In the embodiment illustrated in FIG. 2, the gate dielectric 114 for all of the gates 106/108 is provided by a common layer of gate dielectric material. In other embodiments, the gate dielectric 114 for each of the gates 106/108 may be provided by separate portions of gate dielectric 114. In some embodiments, the gate dielectric 114 may be a multilayer gate dielectric (e.g., with multiple materials used to improve the interface between the fin 104 and the corresponding gate metal). The gate dielectric 114 may be, for example, silicon oxide, aluminum oxide, or a high-k dielectric, such as hafnium oxide. More generally, the gate dielectric 114 may include elements such as hafnium, silicon, oxygen, titanium, tantalum, lanthanum, aluminum, zirconium, barium, strontium, yttrium, lead, scandium, niobium, and zinc. Examples of materials that may be used in the gate dielectric 114 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric 114 to improve the quality of the gate dielectric 114.

Each of the gates 106 may include a gate metal 110 and a hardmask 116. The hardmask 116 may be formed of silicon nitride, silicon carbide, or another suitable material. The gate metal 110 may be disposed between the hardmask 116 and the gate dielectric 114, and the gate dielectric 114 may be disposed between the gate metal 110 and the fin 104. Only one portion of the hardmask 116 is labeled in FIG. 2 for ease of illustration. In some embodiments, the gate metal 110 may be a superconductor, such as aluminum, titanium nitride (e.g., deposited via atomic layer deposition), or niobium titanium nitride. In some embodiments, the hardmask 116 may not be present in the quantum dot device 100 (e.g., a hardmask like the hardmask 116 may be removed during processing, as discussed below). The sides of the gate metal 110 may be substantially parallel, as shown in FIG. 2, and insulating spacers 134 may be disposed on the sides of the gate metal 110 and the hardmask 116. As illustrated in FIG. 2, the spacers 134 may be thicker closer to the fin 104 and thinner farther away from the fin 104. In some embodiments, the spacers 134 may have a convex shape. The spacers 134 may be formed of any suitable material, such as a carbon-doped oxide, silicon nitride, silicon oxide, or other carbides or nitrides (e.g., silicon carbide, silicon nitride doped with carbon, and silicon oxynitride). The gate metal 110 may be any suitable metal, such as titanium nitride.

Each of the gates 108 may include a gate metal 112 and a hardmask 118. The hardmask 118 may be formed of silicon nitride, silicon carbide, or another suitable material. The gate metal 112 may be disposed between the hardmask 118 and the gate dielectric 114, and the gate dielectric 114 may be disposed between the gate metal 112 and the fin 104. In the embodiment illustrated in FIG. 2, the hardmask 118 may extend over the hardmask 116 (and over the gate metal 110 of the gates 106), while in other embodiments, the hardmask 118 may not extend over the gate metal 110 (e.g., as discussed below with reference to FIG. 45). In some embodiments, the gate metal 112 may be a different metal from the gate metal 110; in other embodiments, the gate metal 112 and the gate metal 110 may have the same material composition. In some embodiments, the gate metal 112 may be a superconductor, such as aluminum, titanium nitride (e.g., deposited via atomic layer deposition), or niobium titanium nitride. In some embodiments, the hardmask 118 may not be present in the quantum dot device 100 (e.g., a hardmask like the hardmask 118 may be removed during processing, as discussed below).

The gate 108 may extend between the proximate spacers 134 on the sides of the gate 106-1 and the gate 106-3, as shown in FIG. 2. In some embodiments, the gate metal 112 may extend between the spacers 134 on the sides of the gate 106-1 and the gate 106-3. Thus, the gate metal 112 may have a shape that is substantially complementary to the shape of the spacers 134, as shown. In some embodiments in which the gate dielectric 114 is not a layer shared commonly between the gates 108 and 106, but instead is separately deposited on the fin 104 between the spacers 134 (e.g., as discussed below with reference to FIGS. 40-44), the gate dielectric 114 may extend at least partially up the sides of the spacers 134, and the gate metal 112 may extend between the portions of gate dielectric 114 on the spacers 134. The gate metal 112, like the gate metal 110, may be any suitable metal, such as titanium nitride.

The dimensions of the gates 106/108 may take any suitable values. For example, in some embodiments, the z-height 166 of the gate metal 110 may be between 40 and 75 nanometers (e.g., approximately 50 nanometers); the z-height of the gate metal 112 may be in the same range. In embodiments like the ones illustrated in FIG. 2, the z-height of the gate metal 112 may be greater than the z-height of the gate metal 110. In some embodiments, the length 168 of the gate metal 110 (i.e., in the x-direction) may be between 20 and 40 nanometers (e.g., 30 nanometers). In some embodiments, the distance 170 between adjacent ones of the gates 106 (e.g., as measured from the gate metal 110 of one gate 106 to the gate metal 110 of an adjacent gate 106 in the x-direction, as illustrated in FIG. 2) may be between 40 and 60 nanometers (e.g., 50 nanometers). In some embodiments, the thickness 172 of the spacers 134 may be between 1 and 10 nanometers (e.g., between 3 and 5 nanometers, between 4 and 6 nanometers, or between 4 and 7 nanometers). The length of the gate metal 112 (i.e., in the x-direction) may depend on the dimensions of the gates 106 and the spacers 134, as illustrated in FIG. 2. As indicated in FIG. 1, the gates 106/108 on one fin 104 may extend over the insulating material 128 beyond their respective fins 104 and towards the other fin 104, but may be isolated from their counterpart gates by the intervening insulating material 130.

As shown in FIG. 2, the gates 106 and 108 may be alternatingly arranged along the fin 104 in the x-direction. During operation of the quantum dot device 100, voltages may be applied to the gates 106/108 to adjust the potential energy in the quantum well layer (not shown) in the fin 104 to create quantum wells of varying depths in which quantum dots 142 may form. Only one quantum dot 142 is labeled with a reference numeral in FIGS. 2 and 3 for ease of illustration, but five are indicated as dotted circles in each fin 104, forming what may be referred to as a “quantum dot array.” The location of the quantum dots 142 in FIG. 2 is not intended to indicate a particular geometric positioning of the quantum dots 142. The spacers 134 may themselves provide “passive” barriers between quantum wells under the gates 106/108 in the quantum well layer, and the voltages applied to different ones of the gates 106/108 may adjust the potential energy under the gates 106/108 in the quantum well layer; decreasing the potential energy may form quantum wells, while increasing the potential energy may form quantum barriers.

The fins 104 may include doped regions 140 that may serve as a reservoir of charge carriers for the quantum dot device 100. For example, an n-type doped region 140 may supply electrons for electron-type quantum dots 142, and a p-type doped region 140 may supply holes for hole-type quantum dots 142. In some embodiments, an interface material 141 may be disposed at a surface of a doped region 140, as shown. The interface material 141 may facilitate electrical coupling between a conductive contact (e.g., a conductive via 136, as discussed below) and the doped region 140. The interface material 141 may be any suitable material; for example, in embodiments in which the doped region 140 includes silicon, the interface material 141 may include nickel silicide.

The quantum dot devices 100 disclosed herein may be used to form electron-type or hole-type quantum dots 142. Note that the polarity of the voltages applied to the gates 106/108 to form quantum wells/barriers depend on the charge carriers used in the quantum dot device 100. In embodiments in which the charge carriers are electrons (and thus the quantum dots 142 are electron-type quantum dots), amply negative voltages applied to a gate 106/108 may increase the potential barrier under the gate 106/108, and amply positive voltages applied to a gate 106/108 may decrease the potential barrier under the gate 106/108 (thereby forming a potential well in which an electron-type quantum dot 142 may form). In embodiments in which the charge carriers are holes (and thus the quantum dots 142 are hole-type quantum dots), amply positive voltages applied to a gate 106/108 may increase the potential barrier under the gate 106/108, and amply negative voltages applied to a gate 106 and 108 may decrease the potential barrier under the gate 106/108 (thereby forming a potential well in which a hole-type quantum dot 142 may form). The quantum dot devices 100 disclosed herein may be used to form electron-type or hole-type quantum dots.

Voltages may be applied to each of the gates 106 and 108 separately to adjust the potential energy in the quantum well layer under the gates 106 and 108, and thereby control the formation of quantum dots 142 under each of the gates 106 and 108. Additionally, the relative potential energy profiles under different ones of the gates 106 and 108 allow the quantum dot device 100 to tune the potential interaction between quantum dots 142 under adjacent gates. For example, if two adjacent quantum dots 142 (e.g., one quantum dot 142 under a gate 106 and another quantum dot 142 under a gate 108) are separated by only a short potential barrier, the two quantum dots 142 may interact more strongly than if they were separated by a taller potential barrier. Since the depth of the potential wells/height of the potential barriers under each gate 106/108 may be adjusted by adjusting the voltages on the respective gates 106/108, the differences in potential between adjacent gates 106/108 may be adjusted, and thus the interaction tuned.

In some applications, the gates 108 may be used as plunger gates to enable the formation of quantum dots 142 under the gates 108, while the gates 106 may be used as barrier gates to adjust the potential barrier between quantum dots 142 formed under adjacent gates 108. In other applications, the gates 108 may be used as barrier gates, while the gates 106 are used as plunger gates. In other applications, quantum dots 142 may be formed under all of the gates 106 and 108, or under any desired subset of the gates 106 and 108.

Conductive vias and lines may make contact with the gates 106/108, and to the doped regions 140, to enable electrical connection to the gates 106/108 and the doped regions 140 to be made in desired locations. As shown in FIGS. 1-3, the gates 106 may extend away from the fins 104, and conductive vias 120 may contact the gates 106 (and are drawn in dashed lines in FIG. 2 to indicate their location behind the plane of the drawing). The conductive vias 120 may extend through the hardmask 116 and the hardmask 118 to contact the gate metal 110 of the gates 106. The gates 108 may extend away from the fins 104, and conductive vias 122 may contact the gates 108 (also drawn in dashed lines in FIG. 2 to indicate their location behind the plane of the drawing). The conductive vias 122 may extend through the hardmask 118 to contact the gate metal 112 of the gates 108. Conductive vias 136 may contact the interface material 141 and may thereby make electrical contact with the doped regions 140. The quantum dot device 100 may include further conductive vias and/or lines (not shown) to make electrical contact to the gates 106/108 and/or the doped regions 140, as desired.

During operation, a bias voltage may be applied to the doped regions 140 (e.g., via the conductive vias 136 and the interface material 141) to cause current to flow through the doped regions 140. When the doped regions 140 are doped with an n-type material, this voltage may be positive; when the doped regions 140 are doped with a p-type material, this voltage may be negative. The magnitude of this bias voltage may take any suitable value (e.g., between 0.25 volts and 2 volts).

The conductive vias 120, 122, and 136 may be electrically isolated from each other by an insulating material 130. The insulating material 130 may be any suitable material, such as an interlayer dielectric (ILD). Examples of the insulating material 130 may include silicon oxide, silicon nitride, aluminum oxide, and/or silicon oxynitride. As known in the art of integrated circuit manufacturing, conductive vias and lines may be formed in an iterative process in which layers of structures are formed on top of each other. In some embodiments, the conductive vias 120/122/136 may have a width that is 20 nanometers or greater at their widest point (e.g., 30 nanometers), and a pitch of 80 nanometers or greater (e.g., 100 nanometers). In some embodiments, conductive lines (not shown) included in the quantum dot device 100 may have a width that is 100 nanometers or greater, and a pitch of 100 nanometers or greater. The particular arrangement of conductive vias shown in FIGS. 1-3 is simply illustrative, and any electrical routing arrangement may be implemented.

As discussed above, the structure of the fin 104-1 may be the same as the structure of the fin 104-2; similarly, the construction of gates 106/108 on the fin 104-1 may be the same as the construction of gates 106/108 on the fin 104-2. The gates 106/108 on the fin 104-1 may be mirrored by corresponding gates 106/108 on the parallel fin 104-2, and the insulating material 130 may separate the gates 106/108 on the different fins 104-1 and 104-2. In particular, quantum dots 142 formed in the fin 104-1 (under the gates 106/108) may have counterpart quantum dots 142 in the fin 104-2 (under the corresponding gates 106/108). In some embodiments, the quantum dots 142 in the fin 104-1 may be used as “active” quantum dots in the sense that these quantum dots 142 act as qubits and are controlled (e.g., by voltages applied to the gates 106/108 of the fin 104-1) to perform quantum computations. The quantum dots 142 in the fin 104-2 may be used as “read” quantum dots in the sense that these quantum dots 142 may sense the quantum state of the quantum dots 142 in the fin 104-1 by detecting the electric field generated by the charge in the quantum dots 142 in the fin 104-1, and may convert the quantum state of the quantum dots 142 in the fin 104-1 into electrical signals that may be detected by the gates 106/108 on the fin 104-2. Each quantum dot 142 in the fin 104-1 may be read by its corresponding quantum dot 142 in the fin 104-2. Thus, the quantum dot device 100 enables both quantum computation and the ability to read the results of a quantum computation.

Although not specifically shown in FIGS. 1-3, the quantum dot device 100 may further include one or more accumulation gates used to form a 2DEG in the quantum well area between the area with the quantum dots and the reservoir such as e.g. the doped regions 140 which, as previously described, may serve as a reservoir of charge carriers for the quantum dot device 100. Using such accumulation gates may allow to reduce the number of charge carriers in the area adjacent to the area in which quantum dots are to be formed, so that single charge carriers can be transferred from the reservoir into the quantum dot array. In various embodiments, an accumulation gate may be implemented on either side of an area where a quantum dot is to be formed.

Although also not specifically shown in FIGS. 1-3, some implementations of the quantum dot device 100 further include or are coupled to a magnetic field source used for spin manipulation of the charge carriers in the quantum dots. In various embodiments, e.g. a microwave transmission line or one or more magnets with pulsed gates may be used as a magnetic field source. Once a quantum dot array is initialized by ensuring that a desired number of charge carriers are present in each quantum dot and ensuring the initial spins of these charge carriers, spin manipulation may be carried out with either a single spin or pairs of spin or possibly larger numbers of spins. In some embodiments, single spins may be manipulated using electron spin resonance with a rotating magnetic field (perpendicular to its static field) and on resonance with the transition energy at which the spin flips.

As discussed above, the base 102 and the fin 104 of a quantum dot device 100 may be formed from a semiconductor substrate 144 and a quantum well stack 146 disposed on the semiconductor substrate 144. The quantum well stack 146 may include a quantum well layer in which a 2DEG may form during operation of the quantum dot device 100. The quantum well stack 146 may take any of a number of forms, several of which are illustrated in FIGS. 4-6. The various layers in the quantum well stacks 146 discussed below may be grown on the semiconductor substrate 144 (e.g., using epitaxial processes).

FIG. 4 is a cross-sectional view of a quantum well stack 146 including only a quantum well layer 152. The quantum well layer 152 may be disposed on the semiconductor substrate 144, and may be formed of a material such that, during operation of the quantum dot device 100, a 2DEG may form in the quantum well layer 152 proximate to the upper surface of the quantum well layer 152. The gate dielectric 114 of the gates 106/108 may be disposed on the upper surface of the quantum well layer 152. In some embodiments, the quantum well layer 152 of FIG. 4 may be formed of intrinsic silicon, and the gate dielectric 114 may be formed of silicon oxide; in such an arrangement, during use of the quantum dot device 100, a 2DEG may form in the intrinsic silicon at the interface between the intrinsic silicon and the silicon oxide. In some such embodiments, the intrinsic silicon may be strained, while in other embodiments, the intrinsic silicon may not be strained. The thicknesses (i.e., z-heights) of the layers in the quantum well stack 146 of FIG. 4 may take any suitable values. For example, in some embodiments, the thickness of the quantum well layer 152 (e.g., intrinsic silicon) may be between 0.8 and 1.2 microns.

FIG. 5 is a cross-sectional view of a quantum well stack 146 including a quantum well layer 152 and a barrier layer 154. The quantum well stack 146 may be disposed on a semiconductor substrate 144 such that the barrier layer 154 is disposed between the quantum well layer 152 and the semiconductor substrate 144. The barrier layer 154 may provide a potential barrier between the quantum well layer 152 and the semiconductor substrate 144. As discussed above with reference to FIG. 4, the quantum well layer 152 of FIG. 5 may be formed of a material such that, during operation of the quantum dot device 100, a 2DEG may form in the quantum well layer 152 proximate to the upper surface of the quantum well layer 152. For example, in some embodiments in which the semiconductor substrate 144 is formed of silicon, the quantum well layer 152 of FIG. 5 may be formed of silicon, and the barrier layer 154 may be formed of silicon germanium. The germanium content of this silicon germanium may be 20-80% (e.g., 30%). The thicknesses (i.e., z-heights) of the layers in the quantum well stack 146 of FIG. 5 may take any suitable values. For example, in some embodiments, the thickness of the barrier layer 154 (e.g., silicon germanium) may be between 0 and 400 nanometers. In some embodiments, the thickness of the quantum well layer 152 (e.g., silicon) may be between 5 and 30 nanometers.

FIG. 6 is a cross-sectional view of a quantum well stack 146 including a quantum well layer 152 and a barrier layer 154-1, as well as a buffer layer 176 and an additional barrier layer 154-2. The quantum well stack 146 may be disposed on the semiconductor substrate 144 such that the buffer layer 176 is disposed between the barrier layer 154-1 and the semiconductor substrate 144. The buffer layer 176 may be formed of the same material as the barrier layer 154, and may be present to trap defects that form in this material as it is grown on the semiconductor substrate 144. In some embodiments, the buffer layer 176 may be grown under different conditions (e.g., deposition temperature or growth rate) from the barrier layer 154-1. In particular, the barrier layer 154-1 may be grown under conditions that achieve fewer defects than the buffer layer 176. In some embodiments in which the buffer layer 176 includes silicon germanium, the silicon germanium of the buffer layer 176 may have a germanium content that varies from the semiconductor substrate 144 to the barrier layer 154-1. For example, the silicon germanium of the buffer layer 176 may have a germanium content that varies from zero percent at the silicon semiconductor substrate 144 to a nonzero percent (e.g., 30%) at the barrier layer 154-1. The thicknesses (i.e., z-heights) of the layers in the quantum well stack 146 of FIG. 6 may take any suitable values. For example, in some embodiments, the thickness of the buffer layer 176 (e.g., silicon germanium) may be between 0.3 and 4 microns (e.g., 0.3-2 microns, or 0.5 microns). In some embodiments, the thickness of the barrier layer 154-1 (e.g., silicon germanium) may be between 0 and 400 nanometers. In some embodiments, the thickness of the quantum well layer 152 (e.g., silicon) may be between 5 and 30 nanometers (e.g., 10 nanometers). In some embodiments, the thickness of the barrier layer 154-2 (e.g., silicon germanium) may be between 25 and 75 nanometers (e.g., 32 nanometers).

As discussed above with reference to FIG. 5, the quantum well layer 152 of FIG. 6 may be formed of a material such that, during operation of the quantum dot device 100, a 2DEG may form in the quantum well layer 152 proximate to the upper surface of the quantum well layer 152. For example, in some embodiments in which the semiconductor substrate 144 is formed of silicon, the quantum well layer 152 of FIG. 6 may be formed of silicon, and the barrier layer 154-1 and the buffer layer 176 may be formed of silicon germanium. In some such embodiments, the silicon germanium of the buffer layer 176 may have a germanium content that varies from the semiconductor substrate 144 to the barrier layer 154-1. For example, the silicon germanium of the buffer layer 176 may have a germanium content that varies from zero percent at the silicon semiconductor substrate 144 to a nonzero percent (e.g., 30%) at the barrier layer 154-1. The barrier layer 154-1 may in turn have a germanium content equal to the nonzero percent. In other embodiments, the buffer layer 176 may have a germanium content equal to the germanium content of the barrier layer 154-1, but may be thicker than the barrier layer 154-1 so as to absorb the defects that may arise during growth. The barrier layer 154-2, like the barrier layer 154-1, may provide a potential energy barrier around the quantum well layer 152, and may take the form of any of the embodiments of the barrier layer 154-1. In some embodiments of the quantum well stack 146 of FIG. 6, the buffer layer 176 and/or the barrier layer 154-2 may be omitted.

The semiconductor substrate 144 and the quantum well stack 146 may be distributed between the base 102 and the fins 104 of the quantum dot device 100, as discussed above. This distribution may occur in any of a number of ways. For example, FIGS. 7-13 illustrate example base/fin arrangements 158 that may be used in a quantum dot device 100, in accordance with various embodiments.

In the base/fin arrangement 158 of FIG. 7, the quantum well stack 146 may be included in the fins 104, but not in the base 102. The semiconductor substrate 144 may be included in the base 102, but not in the fins 104. Manufacturing of the base/fin arrangement 158 of FIG. 7 may include fin etching through the quantum well stack 146, stopping when the semiconductor substrate 144 is reached.

In the base/fin arrangement 158 of FIG. 8, the quantum well stack 146 may be included in the fins 104, as well as in a portion of the base 102. A semiconductor substrate 144 may be included in the base 102 as well, but not in the fins 104. Manufacturing of the base/fin arrangement 158 of FIG. 8 may include fin etching that etches partially through the quantum well stack 146, and stops before the semiconductor substrate 144 is reached. FIG. 9 illustrates a particular embodiment of the base/fin arrangement 158 of FIG. 8. In the embodiment of FIG. 9, the quantum well stack 146 of FIG. 6 is used; the fins 104 include the barrier layer 154-1, the quantum well layer 152, and the barrier layer 154-2, while the base 102 includes the buffer layer 176 and the semiconductor substrate 144.

In the base/fin arrangement 158 of FIG. 10, the quantum well stack 146 may be included in the fins 104, but not the base 102. The semiconductor substrate 144 may be partially included in the fins 104, as well as in the base 102. Manufacturing the base/fin arrangement 158 of FIG. 10 may include fin etching that etchs through the quantum well stack 146 and into the semiconductor substrate 144 before stopping. FIG. 11 illustrates a particular embodiment of the base/fin arrangement 158 of FIG. 10. In the embodiment of FIG. 11, the quantum well stack 146 of FIG. 6 is used; the fins 104 include the quantum well stack 146 and a portion of the semiconductor substrate 144, while the base 102 includes the remainder of the semiconductor substrate 144.

Although the fins 104 have been illustrated in many of the preceding figures as substantially rectangular with parallel sidewalls, this is simply for ease of illustration, and the fins 104 may have any suitable shape (e.g., shape appropriate to the manufacturing processes used to form the fins 104). For example, as illustrated in the base/fin arrangement 158 of FIG. 12, in some embodiments, the fins 104 may be tapered. In some embodiments, the fins 104 may taper by 3-10 nanometers in x-width for every 100 nanometers in z-height (e.g., 5 nanometers in x-width for every 100 nanometers in z-height). When the fins 104 are tapered, the wider end of the fins 104 may be the end closest to the base 102, as illustrated in FIG. 12. FIG. 13 illustrates a particular embodiment of the base/fin arrangement 158 of FIG. 12. In FIG. 13, the quantum well stack 146 is included in the tapered fins 104 while a portion of the semiconductor substrate 144 is included in the tapered fins and a portion of the semiconductor substrate 144 provides the base 102.

In the embodiment of the quantum dot device 100 illustrated in FIG. 2, the z-height of the gate metal 112 of the gates 108 may be approximately equal to the sum of the z-height of the gate metal 110 and the z-height of the hardmask 116, as shown. Also in the embodiment of FIG. 2, the gate metal 112 of the gates 108 may not extend in the x-direction beyond the adjacent spacers 134. In other embodiments, the z-height of the gate metal 112 of the gates 108 may be greater than the sum of the z-height of the gate metal 110 and the z-height of the hardmask 116, and in some such embodiments, the gate metal 112 of the gates may extend beyond the spacers 134 in the x-direction.

Exemplary Quantum Circuit Components with Superconducting Qubits

Superconducting qubits are also promising candidates for building a quantum computer. Therefore, these are the types of qubits that may be used in a second exemplary quantum circuit component that may be integrated with on-chip control logic according to embodiments of the present disclosure.

All of superconducting qubits operate based on the Josephson effect, which refers to a macroscopic quantum phenomenon of supercurrent, i.e. a current that, due to zero electrical resistance, flows indefinitely long without any voltage applied, across a device known as a Josephson Junction. Josephson Junctions are integral building blocks in superconducting quantum circuits where they form the basis of quantum circuit elements that can approximate functionality of theoretically designed qubits.

Within superconducting qubit implementations, three classes are typically distinguished: charge qubits, flux qubits, and phase qubits. Transmons, a type of charge qubits with the name being an abbreviation of “transmission line shunted plasma oscillation qubits”, are particularly encouraging because they exhibit reduced sensitivity to charge noise.

In implementations when superconducting qubits are implemented as transmon qubits, two basic elements of superconducting quantum circuits are inductors and capacitors. However, circuits made using only these two elements cannot make a system with two energy levels because, due to the even spacing between the system's energy levels, such circuits will produce harmonic oscillators with a ladder of equivalent states. A nonlinear element is needed to have an effective two-level quantum state system, or qubit. Josephson Junction is an example of such non-linear, non-dissipative circuit element.

Josephson Junctions may form the central circuit elements of a quantum computer based on superconducting qubits. A Josephson Junction may include a thin layer of an insulating material, typically referred to as a barrier or a tunnel barrier, sandwiched between two layers of superconductor. The Josephson Junction acts as a superconducting tunnel junction. Cooper pairs tunnel across the barrier from one superconducting layer to the other. The electrical characteristics of this tunneling are governed by so-called Josephson relations which provide the basic equations governing the dynamics of the Josephson effect:

$$\begin{matrix}I = {I}_{c} sin ϕ & ( 1 ) \\ V = \frac{ℏ}{2 e} \dot{ϕ} & ( 2 )\end{matrix}$$

In these equations, φ is the phase difference in the superconducting wave function across the junction, I_{c} (the critical current) is the maximum current that can tunnel through the junction, which depends on the barrier thickness and the area of the junction, V is the voltage across the Josephson Junction, I is the current flowing through the Josephson Junction, ℏ is the reduced Planck's constant, and e is electron's charge. Equations (1) and (2) can be combined to give an equation (3):

$$V = \frac{ℏ}{2 e {I}_{c} cos ϕ} \dot{I} \qquad ( 3 )$$

Equation (3) looks like the equation for an inductor with inductance L:

$$L = \frac{ℏ}{2 e {I}_{C} cos ϕ} \qquad ( 4 )$$

Since inductance is a function of φ, which itself is a function of I, the inductance of a Josephson Junction is non-linear, which makes an LC circuit formed using a Josephson Junction as the inductor have uneven spacing between its energy states.

The foregoing provides an illustration of using a Josephson Junction in a transmon, which is one class of superconducting qubit. In other classes of superconducting qubits, Josephson Junctions combined with other circuit elements have similar functionality of providing the non-linearity necessary for forming an effective two-level quantum state, or qubit. In other words, when implemented in combination with other circuit elements (e.g. capacitors in transmons or superconducting loops in flux qubits), one or more Josephson Junctions allow realizing a quantum circuit element which has uneven spacing between its energy levels resulting in a unique ground and excited state system for the qubit. This is illustrated in FIG. 14, providing a schematic illustration of a superconducting quantum circuit 200, according to some embodiments of the present disclosure. As shown in FIG. 14, an exemplary superconducting quantum circuit 200 includes two or more qubits: 202-1 and 202-2. Qubits 202-1 and 202-2 may be identical and thus the discussion of FIG. 14 refers generally to the “qubit 202,” and the same applies to referring to Josephson Junctions 204-1 and 204-2 generally as “Josephson Junctions 204” and referring to circuit elements 206-1 and 206-2 generally as “circuit elements 206.” As shown in FIG. 14, each of the superconducting qubits 202 may include one or more Josephson Junctions 204 connected to one or more other circuit elements 206, which, in combination with the Josephson Junction(s) 204, form a non-linear circuit providing a unique two-level quantum state for the qubit. The circuit elements 206 could be e.g. capacitors in transmons or superconducting loops in flux qubits.

As also shown in FIG. 14, an exemplary superconducting quantum circuit 200 typically includes means 208 for providing external control of qubits 202 and means 210 for providing internal control of qubits 202. In this context, “external control” refers to controlling the qubits 202 from outside of, e.g, an integrated circuit (IC) chip comprising the qubits, including control by a user of a quantum computer, while “internal control” refers to controlling the qubits 202 within the IC chip. For example, if qubits 202 are transmon qubits, external control may be implemented by means of flux bias lines (also known as “flux lines” and “flux coil lines”) and by means of readout and drive lines (also known as “microwave lines” since qubits are typically designed to operate with microwave signals), described in greater detail below. On the other hand, internal control lines for such qubits may be implemented by means of resonators, e.g., coupling and readout resonators, also described in greater detail below.

Any one of the qubits 202, the external control means 208, and the external control means 210 of the quantum circuit 200 may be provided on, over, or at least partially embedded in a substrate (not shown in FIG. 14).

FIG. 15 provides a schematic illustration of an exemplary physical layout of a superconducting quantum circuit 211 where qubits are implemented as transmons, according to some embodiments of the present disclosure.

Similar to FIG. 14, FIG. 15 illustrates two qubits 202. In addition, FIG. 15 illustrates flux bias lines 212, microwave lines 214, a coupling resonator 216, a readout resonator 218, and wirebonding pads 220 and 222. The flux bias lines 212 and the microwave lines 214 may be viewed as examples of the external control means 208 shown in FIG. 14. The coupling resonator 216 and the readout resonator 218 may be viewed as examples of the internal control means 210 shown in FIG. 14.

Running a current through the flux bias lines 212, provided from the wirebonding pads 220, allows tuning (i.e. changing) the frequency of the corresponding qubits 202 to which each line 212 is connected. In general, it operates in the following manner. As a result of running the current in a particular flux bias line 212, magnetic field is created around the line. If such a magnetic field is in sufficient proximity to the qubit 202, e.g. by a portion of the flux bias line 212 being provided next to the qubit 202, the magnetic field couples to the qubit, thereby changing the spacing between the energy levels of the qubit. This, in turn, changes the frequency of the qubit since the frequency is directly related to the spacing between the energy levels via Planck's equation. The Planck's equation is E=hv, where E is the energy (in this case the energy difference between energy levels of a qubit), h is the Planck's constant and v is the frequency (in this case the frequency of the qubit). As this equation illustrates, if E changes, then v changes. Provided there is sufficient multiplexing, different currents can be sent down each of the flux lines allowing for independent tuning of the various qubits.

Typically, the qubit frequency may be controlled in order to bring the frequency either closer to or further away from another resonant item, for example a coupling resonator such as 216 shown in FIG. 15 that connects two or more qubits together, as may be desired in a particular setting.

For example, if it is desirable that a first qubit 202 (e.g. the qubit 202 shown on the left side of FIG. 15) and a second qubit 202 (e.g. the qubit 202 shown on the right side of FIG. 15) interact, via the coupling resonator 216 connecting these qubits, then both qubits 202 may need to be tuned to be at nearly the same frequency. One way in which such two qubits could interact is that, if the frequency of the first qubit 202 is tuned very close to the resonant frequency of the coupling resonator 216, the first qubit can, when in the excited state, relax back down to the ground state by emitting a photon (similar to how an excited atom would relax) that would resonate within the coupling resonator 216. If the second qubit 202 is also at this energy (i.e. if the frequency of the second qubit is also tuned very close to the resonant frequency of the coupling resonator 216), then it can absorb the photon emitted from the first qubit, via the coupling resonator 216, and be excited from it's ground state to an excited state. Thus, the two qubits interact in that a state of one qubit is controlled by the state of another qubit. In other scenarios, two qubits could interact via a coupling resonator at specific frequencies, but these three elements do not have to be tuned to be at nearly the same frequency with one another. In general, two or more qubits could be configured to interact with one another by tuning their frequencies to specific values or ranges.

On the other hand, it may sometimes be desirable that two qubits coupled by a coupling resonator do not interact, i.e. the qubits are independent. In this case, by applying magnetic flux, by means of controlling the current in the appropriate flux bias line, to one qubit it is possible to cause the frequency of the qubit to change enough so that the photon it could emit no longer has the right frequency to resonate on the coupling resonator. If there is nowhere for such a frequency-detuned photon to go, the qubit will be better isolated from its surroundings and will live longer in its current state. Thus, in general, two or more qubits could be configured to avoid or eliminate interactions with one another by tuning their frequencies to specific values or ranges.

The state(s) of each qubit 202 may be read by way of its corresponding readout resonator 218. As explained below, the qubit 202 induces a resonant frequency in the readout resonator 218. This resonant frequency is then passed to the microwave lines 214 and communicated to the pads 222.

To that end, a readout resonator 218 may be provided for each qubit. The readout resonator 218 may be a transmission line that includes a capacitive connection to ground on one side and is either shorted to the ground on the other side (for a quarter wavelength resonator) or has a capacitive connection to ground (for a half wavelength resonator), which results in oscillations within the transmission line (resonance), with the resonant frequency of the oscillations being close to the frequency of the qubit. The readout resonator 218 is coupled to the qubit by being in sufficient proximity to the qubit 202, more specifically in sufficient proximity to the capacitor of the qubit 202, when the qubit is implemented as a transmon, either through capacitive or inductive coupling. Due to a coupling between the readout resonator 218 and the qubit 202, changes in the state of the qubit 202 result in changes of the resonant frequency of the readout resonator 218. In turn, because the readout resonator 218 is in sufficient proximity to the microwave line 214, changes in the resonant frequency of the readout resonator 218 induce changes in the current in the microwave line 214, and that current can be read externally via the wire bonding pads 222.

The coupling resonator 216 allows coupling different qubits together, e.g. as described above, in order to realize quantum logic gates. The coupling resonator 216 is similar to the readout resonator 218 in that it is a transmission line that includes capacitive connections to ground on both sides (i.e. a half wavelength resonator), which also results in oscillations within the coupling resonator 216. Each side of the coupling resonator 216 is coupled (again, either capacitively or inductively) to a respective qubit by being in sufficient proximity to the qubit, namely in sufficient proximity to the capacitor of the qubit, when the qubit is implemented as a transmon. Because each side of the coupling resonator 216 has coupling with a respective different qubit, the two qubits are coupled together through the coupling resonator 216. In this manner, state of one qubit depends on the state of the other qubit, and the other way around. Thus, coupling resonators may be employed in order to use a state of one qubit to control a state of another qubit.

In some implementations, the microwave line 214 may be used to not only readout the state of the qubits as described above, but also to control the state of the qubits. When a single microwave line is used for this purpose, the line operates in a half-duplex mode where, at some times, it is configured to readout the state of the qubits, and, at other times, it is configured to control the state of the qubits. In other implementations, microwave lines such as the line 214 shown in FIG. 15 may be used to only readout the state of the qubits as described above, while separate drive lines such as e.g. drive lines 224 shown in FIG. 15, may be used to control the state of the qubits. In such implementations, the microwave lines used for readout may be referred to as readout lines (e.g. readout line 214), while microwave lines used for controlling the state of the qubits may be referred to as drive lines (e.g. drive lines 224). The drive lines 224 may control the state of their respective qubits 202 by providing, using e.g. wirebonding pads 226 as shown in FIG. 15, a microwave pulse at the qubit frequency, which in turn stimulates (i.e. triggers) a transition between the states of the qubit. By varying the length of this pulse, a partial transition can be stimulated, giving a superposition of the states of the qubit.

Flux bias lines, microwave lines, coupling resonators, drive lines, and readout resonators, such as e.g. those described above, together form interconnects for supporting propagation of microwave signals. Further, any other connections for providing direct electrical interconnection between different quantum circuit elements and components, such as e.g. connections from electrodes of Josephson Junctions to plates of the capacitors or to superconducting loops of superconducting quantum interference devices (SQUIDS) or connections between two ground lines of a particular transmission line for equalizing electrostatic potential on the two ground lines, are also referred to herein as interconnects. Still further, the term “interconnect” may also be used to refer to elements providing electrical interconnections between quantum circuit elements and components and non-quantum circuit elements, which may also be provided in a quantum circuit, as well as to electrical interconnections between various non-quantum circuit elements provided in a quantum circuit. Examples of non-quantum circuit elements which may be provided in a quantum circuit may include various analog and/or digital systems, e.g. analog to digital converters, mixers, multiplexers, amplifiers, etc.

In various embodiments, the interconnects as shown in FIG. 15 could have different shapes and layouts. For example, some interconnects may comprise more curves and turns while other interconnects may comprise less curves and turns, and some interconnects may comprise substantially straight lines. In some embodiments, various interconnects may intersect one another, in such a manner that they don't make an electrical connection, which can be done by using e.g. a bridge, bridging one interconnect over the other. As long as these interconnects operate in accordance with use of these interconnects as known in the art for which some exemplary principles were described above, quantum circuits with different shapes and layouts of the interconnects than those illustrated in FIG. 15 are all within the scope of the present disclosure.

Coupling resonators and readout resonators may be configured for capacitive coupling to other circuit elements at one or both ends in order to have resonant oscillations, whereas flux bias lines and microwave lines may be similar to conventional microwave transmission lines because there is no resonance in these lines. Each one of these interconnects may be implemented as any suitable architecture of a microwave transmission line, such as e.g. a coplanar waveguide, a stripline, a microstrip line, or an inverted microstrip line. Typical materials to make the interconnects include aluminum (Al), niobium (Nb), niobium nitride (NbN), titanium nitride (TiN), molybdenum rhenium (MoRe), and niobium titanium nitride (NbTiN), all of which are particular types of superconductors. However, in various embodiments, other suitable superconductors and alloys of superconductors may be used as well.

While FIGS. 14 and 15 illustrate examples of quantum circuits comprising only two qubits 202, embodiments with any larger number of qubits are possible and are within the scope of the present disclosure. Furthermore, while FIGS. 14 and 15 illustrate embodiments specific to transmons, subject matter disclosed herein is not limited in this regard and may include other embodiments of quantum circuits implementing other types of superconducting qubits that would also utilize Josephson Junctions as described herein, all of which are within the scope of the present disclosure.

Control Logic Integrated with a Quantum Circuit

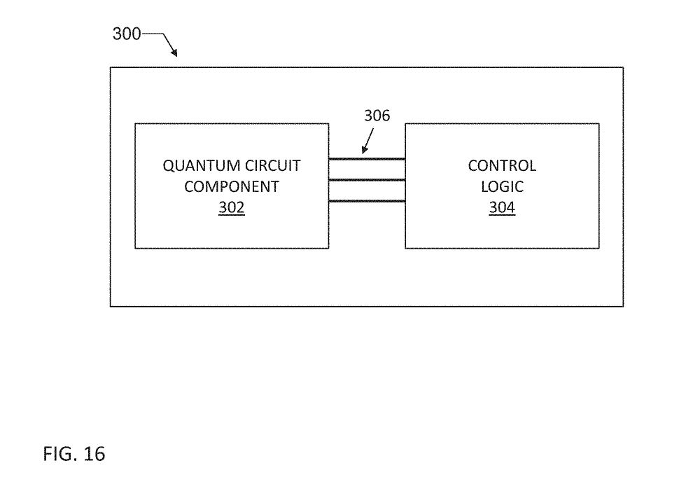

FIG. 16 provides a schematic illustration of a quantum circuit assembly 300 that includes a quantum circuit component 302 integrated with a control logic 304 on the same die.

In general, the term “die” refers to a small block of semiconductor material/substrate on which a particular functional circuit is fabricated. An IC chip, also referred to as simply a chip or a microchip, sometimes refers to a semiconductor wafer on which thousands or millions of such devices or dies are fabricated. Other times, an IC chip refers to a portion of a semiconductor wafer (e.g. after the wafer has been diced) containing one or more dies. In general, a device is referred to as “integrated” if it is manufactured on one or more dies of an IC chip.

The quantum circuit component 302 may be any component that includes a plurality of qubits which may be used to perform quantum processing operations. For example, the quantum circuit component 302 may include one or more quantum dot devices 100 or one or more devices 200 or 211 implementing superconducting qubits. However, in general, the quantum circuit component 300 may include any type of qubits, all of which are within the scope of the present disclosure.

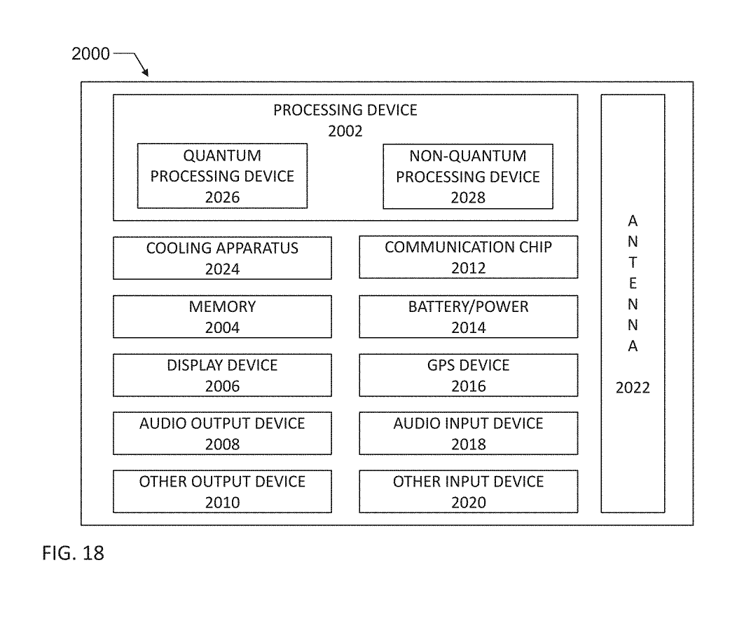

As noted above, the control logic 304 is configured to control operation of the quantum circuit component 302. In some embodiments, the control logic 304 may provide peripheral logic to support the operation of the quantum computing component 302. For example, the control logic 304 may control the performance of a read operation, control the performance of a write operation, control the clearing of quantum bits, etc. The control logic 304 may also perform conventional computing functions to supplement the computing functions which may be provided by the quantum circuit component 302. For example, the control logic 304 may interface with one or more of the other components of a quantum computing device, such as e.g. a quantum computing device 2000 described below, in a conventional manner, and may serve as an interface between the quantum circuit component 302 and conventional components. In some embodiments, the control logic 304 may be implemented in or may be used to implement a non-quantum processing device 2028 described below with reference to FIG. 18.

In various embodiments, mechanisms by which the control logic 304 controls operation of the quantum circuit component 302 may be take the form of an entirely hardware embodiment, an entirely software embodiment (including firmware, resident software, micro-code, etc.) or an embodiment combining software and hardware aspects. For example, the control logic 304 may implement an algorithm executed by one or more processing units, e.g. one or more microprocessors, of one or more computers. In various embodiments, aspects of the present disclosure may take the form of a computer program product embodied in one or more computer readable medium(s), preferably non-transitory, having computer readable program code embodied, e.g., stored, thereon. In various embodiments, such a computer program may, for example, be downloaded (updated) to the control logic 304 or be stored upon manufacturing of the control logic 304.

In some embodiments, the control logic 304 may include at least one processor and at least one memory element (not shown in FIG. 16), along with any other suitable hardware and/or software to enable its intended functionality of controlling operation of the quantum circuit component(s) 302 as described herein. Such a processor of the control logic can execute software or an algorithm to perform the activities as discussed herein. A processor of the control logic 304 may be configured to communicatively couple to other system elements via one or more interconnects or buses. Such a processor may include any combination of hardware, software, or firmware providing programmable logic, including by way of non-limiting example a microprocessor, a digital signal processor (DSP), a field-programmable gate array (FPGA), a programmable logic array (PLA), an application specific integrated circuit (ASIC), or a virtual machine processor. The processor of the control logic 304 may be communicatively coupled to the memory element of the control logic 304, for example in a direct-memory access (DMA) configuration. Such a memory element of the control logic 304 may include any suitable volatile or non-volatile memory technology, including double data rate (DDR) random access memory (RAM), synchronous RAM (SRAM), dynamic RAM (DRAM), flash, read-only memory (ROM), optical media, virtual memory regions, magnetic or tape memory, or any other suitable technology. Any of the memory items discussed herein should be construed as being encompassed within the broad term “memory element.” The information being tracked or sent to the control logic 304 could be provided in any database, register, control list, cache, or storage structure, all of which can be referenced at any suitable timeframe. Any such storage options may be included within the broad term “memory element” of the control logic 304 as used herein. Similarly, any of the potential processing elements, modules, and machines described herein should be construed as being encompassed within the broad term “processor” of the control logic 304. The control logic 304 can further include suitable interfaces for receiving, transmitting, and/or otherwise communicating data or information in a network environment.

As shown in FIG. 16, the logic 304 may be communicatively connected to the quantum circuit component 302 using one or more interconnects 306. The interconnects 306 may include any type of interconnects suitable for enabling the control logic 304 to control the quantum circuit component 302. For example, the interconnects 306 may include electrically conductive structures that would allow the control logic 304 to apply appropriate voltages to any of the plunger, barrier, and/or accumulation gates of one or more quantum dot arrays that may be realized in the quantum circuit component 302. In some embodiments, the interconnects 306 may include electrically conductive structures that support direct currents. In some embodiments, the interconnects 306 may include electrically conductive structures that support microwave currents or pulsed currents at microwave frequencies. Such interconnects may be implemented as microwave transmission lines using various transmission line architectures, such as e.g. a coplanar waveguide, a stripline, a microstrip line, or an inverted microstrip line. In some embodiments, the interconnects 306 may be made from superconducting materials, such as, but not limited to, aluminum (Al), niobium (Nb), niobium nitride (NbN), titanium nitride (TiN), and niobium titanium nitride (NbTiN), as well as other suitable superconductors and/or their alloys.

In various embodiments, the interconnects 306 as shown in FIG. 16 could have different shapes and layouts. For example, some interconnects may comprise curves and turns while other interconnects may comprise substantially straight lines. In some embodiments, various interconnects may intersect one another, in such a manner that they do not make an electrical connection, which can be done by using e.g. a bridge, bridging one interconnect over the other. As long as these interconnects operate in accordance with use of these interconnects as known in the art for which some exemplary principles are described herein, quantum circuits assemblies with interconnects having different shapes and layouts than those illustrated in FIG. 16 with the interconnects 306 are all within the scope of the present disclosure.

The control that the control logic 304 would exercise over the operation of the quantum circuit component 302 would depend on the type of qubits that the quantum circuit component uses.

For example, if the quantum circuit component uses quantum dot qubits, the control logic 304 could be configured to apply appropriate voltages to any one of plunger, barrier gates, and/or accumulation gates in order to initialize and manipulate the quantum dots. Some examples of controlling the voltages on these gates are explained above with reference to the quantum dot device 100. In the interests of brevity, these explanations are not repeated in detail here, but it is understood that, unless specified otherwise, all of the control mechanisms explained above may be performed by the control logic 304 shown in FIG. 16.

In some embodiments, the control logic 304 may be configured to determine variations in gate voltages for forming different quantum dots. To that end, the control logic 304 may be configured to characterize formation of each quantum dot, i.e. to characterize at which gate voltage configurations the charge carriers can be exchanged between the neighboring quantum dots. The control logic may also be configured to read out the exchange of charge carriers in a first quantum dot array by reading out the transconductance of a set of quantum dots in a second quantum dot array adjacent to the first quantum dot array used as a single-electron transistor or any other suitable implementation of a single-electron transistor. The variations in gate voltages may then be determined based on an outcome of the characterization of the formation of the quantum dots.

In general, the term “plunger gate” is used to describe a gate under which an electro-static quantum dot is formed. By controlling the voltage applied to a plunger gate, the control logic 304 is able to modulate the electric field underneath that gate to create an energy valley (assuming electron-based quantum dot qubits) between the tunnel barriers created by the barrier gates.

In general, the term “barrier gate” is used to describe a gate used to set a tunnel barrier (i.e. a potential barrier) between either two plunger gates (i.e. controlling tunneling of charge carrier(s), e.g. electrons, from one quantum dot to an adjacent quantum dot) or a plunger gate and an accumulation gate. When the control logic 304 changes the voltage applied to a barrier gate, it changes the height of the tunnel barrier. When a barrier gate is used to set a tunnel barrier between two plunger gates, the barrier gate may be used to transfer charge carriers between quantum dots that may be formed under these plunger gates. When a barrier gate is used to set a tunnel barrier between a plunger gate and an accumulation gate, the barrier gate may be used to transfer charge carriers in and out of the quantum dot array via the accumulation gate.

In general, the term “accumulation gate” is used to describe a gate used to form a 2DEG in an area that is between the area where the quantum dots may be formed and a charge carrier reservoir. Changing the voltage applied to the accumulation gate allows the control logic 304 to control the number of charge carriers in the area under the accumulation gate. For example, changing the voltage applied to the accumulation gate allows reducing the number of charge carriers in the area under the gate so that single charge carriers can be transferred from the reservoir into the quantum dot array, and vice versa.

In some embodiments of quantum dot qubits, the control logic 304 may be configured to

The control logic 304 may further be configured to control spins of charge carriers in quantum dots of the one or more qubits by controlling a magnetic field generated by the magnetic field generator. In this manner, the control logic 304 may be able to initialize and manipulate spins of the charge carriers in the quantum dots to implement qubit operations. Typically, the magnetic field generator generates a microwave magnetic field of a frequency matching that of the qubit. If the magnetic field for the quantum circuit component 302 is generated by a microwave transmission line, then the control logic may set/manipulate the spins of the charge carriers by applying appropriate pulse sequences to manipulate spin precession. Alternatively, the magnetic field for the quantum circuit component 302 is generated by a magnet with one or more pulsed gates.

In another example, if the quantum circuit component uses superconducting qubits, the control logic 304 could be configured to provide appropriate currents in any of flux bias lines, microwave lines, and/or drive lines in order to initialize and manipulate the superconducting dots. Some examples of controlling the currents in these lines are explained above with reference to the devices 200 and 211. In the interests of brevity, these explanations are not repeated in detail here, but it is understood that, unless specified otherwise, all of the control mechanisms explained above may be performed by the control logic 304 shown in FIG. 16.

In some embodiments of superconducting qubits, the control logic 304 may be configured to detect current(s) in microwave line(s) and to control the operation of the quantum circuit component 302 based on the detected current(s). By detecting current in a microwave line, the control logic 304 is able to assess/detect the state of the corresponding qubit(s) to which the line is coupled. In some further embodiments, the control logic 304 may further be configured to also control the current(s) in microwave line(s). By controlling the current in a microwave line, control logic is configured to control (e.g. change) the state of the corresponding qubit(s) to which the line is coupled. In such further embodiments, the control logic may be configured to switch operation of the microwave lines between controlling the current in the microwave lines to control states of the qubit(s) and detecting the current in the microwave lines to detect the states of the qubit(s). Thus, the control logic 304 can operate the microwave lines in a half-duplex mode where the microwave lines are either used for readout or for setting the state(s) of the corresponding qubits.

In some embodiments of superconducting qubits, the control logic 304 may be configured to control current(s) in one or more drive lines. By controlling the current in a drive line, control logic is configured to control (e.g. change) the state of the corresponding qubit(s) to which the line is coupled. When drive lines are used, the control logic can use the microwave lines for readout of the state(s) of the corresponding qubits and use the drive lines for setting the state(s) of the qubits, which would be an alternative to the half-duplex mode implementation described above. For example, the control logic 304 may be configured to control the current in the one or more drive lines by ensuring provision of one or more pulses of the current at a frequency of the one or more qubits. In this manner, the control logic 304 can provide a microwave pulse at the qubit frequency, which in turn stimulates (i.e. triggers) a transition between the states of the corresponding qubit. In some embodiments, the control logic 304 may be configured to control a duration of these pulses. By varying the length/duration of the pulse(s), the control logic 304 can stimulate a partial transition between the states of the corresponding qubit, giving a superposition of the states of the qubit.

In some embodiments, the control logic 304 may be configured to determine the values of the control signals applied to the elements of the quantum circuit component 302, e.g. determine the voltages to be applied to the various gates of a quantum dot device or determine the currents to be provided in various lines of a superconducting qubit device. In other embodiments, the control logic 304 may be pre-programmed with at least some of the control parameters, e.g. with the values for the voltages to be applied to the various gates of a quantum dot device such as e.g. the device 100 during the initialization of the device.

Instead of providing the control functions from a chip that is typically remote from the quantum circuit component 302, the integrated quantum circuit assembly 300 addresses some of the above mentioned shortcomings of such remote control by providing one or more control functions on-chip, onto the same die, with the quantum circuit component.

Fabricating Control Logic Integrated with a Quantum Circuit

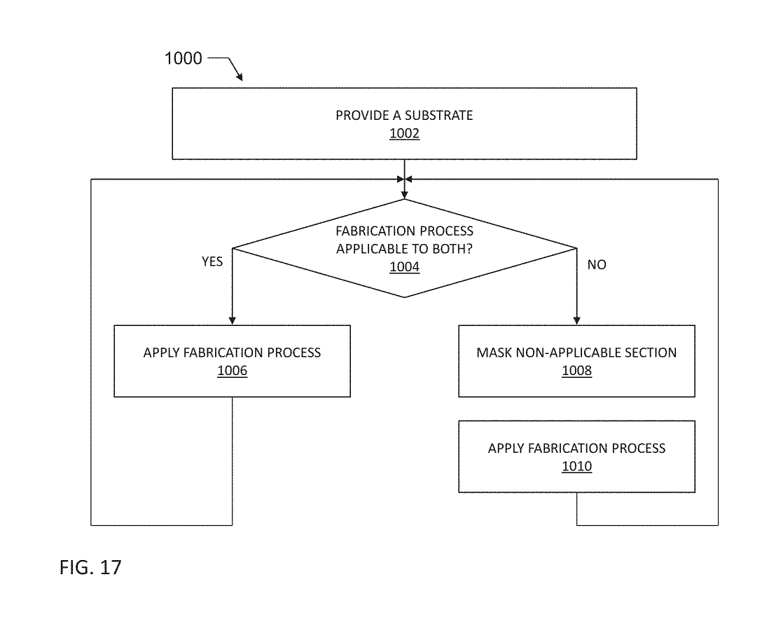

There are many non-trivial technical challenges and considerations when designing an integrated quantum circuit assembly 300. FIG. 17 provides a flow chart of an exemplary method 1000 for fabricating control logic integrated with a quantum circuit component in such an assembly, according to some embodiments of the present disclosure.

Although the operations discussed below with reference to the method 1000 are illustrated in a particular order and depicted once each, these operations may be repeated or performed in a different order (e.g., in parallel), as suitable. Additionally, various operations may be omitted, as suitable. Various operations of the method 1000 may be illustrated with reference to one or more of the embodiments discussed above, but the method 1000 may be used to manufacture any suitable quantum circuit assembly comprising control logic integrated with a quantum circuit component on a single die according to any embodiments disclosed herein.

The method 1000 may begin with providing a substrate on which a quantum circuit assembly 300 will be provided (process 1002 of FIG. 17). The substrate may comprise any substrate suitable for realizing quantum circuit components described herein. In one implementation, the substrate may be a crystalline substrate such as, but not limited to a silicon or a sapphire substrate, and may be provided as a wafer or a portion thereof. In other implementations, the substrate may be non-crystalline. In general, any material that provides sufficient advantages (e.g. sufficiently good electrical isolation and/or ability to apply known fabrication and processing techniques) to outweigh the possible disadvantages (e.g. negative effects of various defects), and that may serve as a foundation upon which a quantum circuit may be built, falls within the spirit and scope of the present disclosure. Additional examples of substrates include silicon-on-insulator (SOI) substrates, III-V substrates, and quartz substrates.

In some embodiments, the substrate may be cleaned to remove surface-bound organic and metallic contaminants, as well as subsurface contamination, prior to fabrication of the quantum circuit component 302 and the control logic 304. In some embodiments, cleaning may be carried out using e.g. a chemical solutions (such as peroxide), and/or with ultraviolet (UV) radiation combined with ozone, and/or oxidizing the surface (e.g., using thermal oxidation) then removing the oxide (e.g. using hydrofluoric acid (HF)).

Next, the substrate is selectively processed to form both the quantum circuit component 302 and the control logic 304. Since some fabrication processes may be applicable to fabricating the one but not the other, the method 1000 may proceed to determining whether a particular fabrication process is applicable to both the quantum circuit component 302 and the control logic 304 at each given fabrication stage (process 1004 of FIG. 17).

A particular fabrication process may include any known techniques for fabricating parts of the quantum circuit component 302 and the control logic 304. At some stages, a fabrication process may include patterning and then etching, as known in the art. For example, patterning may include patterning using photolithographic techniques, while etching may include any combination of dry and wet etch chemistry with the appropriate chemistry selected depending on the materials included in the assembly 300, as known in the art for forming the quantum circuit component 302 and the control logic 304 individually. At other stages, a fabrication process may include depositing conducting/superconducting materials using e.g. atomic layer deposition (ALD), physical vapor deposition (PVD) (e.g. evaporative deposition, magnetron sputtering, or e-beam deposition), chemical vapor deposition (CVD), or electroplating, as known in the art. At still other stages, a fabrication process may include planarizing the assembly, e.g. using a chemical mechanical polishing (CMP) technique.

In some embodiments, fabrication processes used in the method 1000 may use standard Complementary Metal-Oxide Semiconductor (CMOS) or Bi-CMOS (i.e. technology combining CMOS with bipolar junction transistor) processes, possibly with additional custom fabrication steps.

If it is determined in 1004 that a particular fabrication process is applicable to both the quantum circuit component 302 and the control logic 304, then that fabrication process is carried out for the entire structure on the substrate (process 1006 of FIG. 17). If, at that time, one or more sections of the structure are masked, e.g. as a result of masking those sections for the previous fabrication process, then prior to applying the fabrication process at 1006 masks can be removed from these sections.

If, on the other hand, it is determined in 1004 that a particular fabrication process is applicable to only one of the quantum circuit component 302 and the control logic 304 but not the other, then a section of the substrate to which that fabrication process is not applicable is masked for processing (process 1008 of FIG. 17) and the fabrication process is then carried out (process 1010 of FIG. 17). As a result of the masking, the fabrication process is carried out only for the section of the substrate to which the process is applicable. One example of a fabrication process which may be applicable to one section but not another includes integration of a second metal gate in the quantum dot based qubits (as a part of fabricating the quantum circuit component 302), as opposed to using only one metal gate in the control logic section of the chip (as a part of fabricating the control logic 304). Another example includes integration of specific materials in the qubit area only, e.g. providing cobalt for the micromagnets in quantum dot based designs or depositing superconducting materials for superconducting resonators and waveguides in quantum circuits. Other examples include forming tunnel junctions in Josephson Junctions made of specific stack(s) of material(s) which are not part of the regular (Bi)CMOS process, selectively implanting dopants in the qubit array but not in the control logic section of the chip, etc.

In some embodiments, a section of the substrate may be masked against application of a particular fabrication process using oxide or nitride. This may be carried out e.g. by providing a layer of oxide or nitride across the entire wafer and then using lithography as known in the art to pattern and etch it off in certain regions (i.e. in regions where masking is not needed).

Processes 1004-1010 shown in FIG. 17 may be performed iteratively, until the quantum circuit component 302 and the control logic 304 are provided on a single substrate. After the quantum circuit component 302 and the control logic 304 have been fabricated on the substrate, whatever masks may still be remaining, may then be removed. In some embodiments, a mask as deposited in process 1008 may be removed using wet etch, as known in the art.

### Exemplary Quantum Computing Device

In various embodiments, quantum circuit assemblies that include quantum circuit component(s) integrated with their control logic on a single die as described herein may be used to implement components associated with a quantum integrated circuit (IC). Such components may include those that are mounted on or embedded in a quantum IC, or those connected to a quantum IC. The quantum IC may be either analog or digital and may be used in a number of applications within or associated with quantum systems, such as e.g. quantum processors, quantum amplifiers, quantum sensors, etc., depending on the components associated with the integrated circuit. The integrated circuit may be employed as part of a chipset for executing one or more related functions in a quantum system.

FIG. 18 provides a schematic illustration of an exemplary quantum computing device 2000 that may include control logic integrated with any of quantum circuit components as described herein, according to some embodiments of the present disclosure.

A number of components are illustrated in FIG. 18 as included in the quantum computing device 2000, but any one or more of these components may be omitted or duplicated, as suitable for the application. In some embodiments, some or all of the components included in the quantum computing device 2000 may be attached to one or more printed circuit boards (e.g., a motherboard). In some embodiments, various ones of these components may be fabricated onto a single system-on-a-chip (SoC) die. Additionally, in various embodiments, the quantum computing device 2000 may not include one or more of the components illustrated in FIG. 18, but the quantum computing device 2000 may include interface circuitry for coupling to the one or more components. For example, the quantum computing device 2000 may not include a display device 2006, but may include display device interface circuitry (e.g., a connector and driver circuitry) to which a display device 2006 may be coupled. In another set of examples, the quantum computing device 2000 may not include an audio input device 2018 or an audio output device 2008, but may include audio input or output device interface circuitry (e.g., connectors and supporting circuitry) to which an audio input device 2018 or audio output device 2008 may be coupled.

The quantum computing device 2000 may include a processing device 2002 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2002 may include a quantum processing device 2026 (e.g., one or more quantum processing devices), and a non-quantum processing device 2028 (e.g., one or more non-quantum processing devices). The quantum processing device 2026 may include one or more of the quantum circuit components disclosed herein, and may perform data processing by performing operations on the qubits that may be generated in the quantum circuits, and monitoring the result of those operations. For example, as discussed above, different qubits may be allowed to interact, the quantum states of different qubits may be set or transformed, and the quantum states of qubits may be read (e.g., by another qubit via a coupling resonator or externally via a readout resonator). The quantum processing device 2026 may be a universal quantum processor, or specialized quantum processor configured to run one or more particular quantum algorithms. In some embodiments, the quantum processing device 2026 may execute algorithms that are particularly suitable for quantum computers, such as cryptographic algorithms that utilize prime factorization, encryption/decryption, algorithms to optimize chemical reactions, algorithms to model protein folding, etc. The quantum processing device 2026 may also include support circuitry to support the processing capability of the quantum processing device 2026, such as input/output channels, multiplexers, signal mixers, quantum amplifiers, and analog-to-digital converters.

As noted above, the processing device 2002 may include a non-quantum processing device 2028. In some embodiments, the non-quantum processing device 2028 may include, or be included in, the on-chip control logic disclosed herein, configured to control operation of the quantum processing device 2026 as described herein. In some embodiments, the non-quantum processing device 2028 may provide peripheral logic to support the operation of the quantum processing device 2026. For example, the non-quantum processing device 2028 may control the performance of a read operation, control the performance of a write operation, control the clearing of quantum bits, etc. The non-quantum processing device 2028 may also perform conventional computing functions to supplement the computing functions provided by the quantum processing device 2026. For example, the non-quantum processing device 2028 may interface with one or more of the other components of the quantum computing device 2000 (e.g., the communication chip 2012 discussed below, the display device 2006 discussed below, etc.) in a conventional manner, and may serve as an interface between the quantum processing device 2026 and conventional components. The non-quantum processing device 2028 may include one or more digital signal processors (DSPs), application-specific integrated circuits (ASICs), central processing units (CPUs), graphics processing units (GPUs), crypto processors (specialized processors that execute cryptographic algorithms within hardware), server processors, or any other suitable processing devices.

The quantum computing device 2000 may include a memory 2004, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the states of qubits in the quantum processing device 2026 may be read and stored in the memory 2004. In some embodiments, the memory 2004 may include memory that shares a die with the non-quantum processing device 2028. This memory may be used as cache memory and may include embedded dynamic random access memory (eDRAM) or spin transfer torque magnetic random-access memory (STT-MRAM).

The quantum computing device 2000 may include a cooling apparatus 2024. The cooling apparatus 2024 may maintain the quantum processing device 2026 at a predetermined low temperature during operation to reduce the effects of scattering in the quantum processing device 2026. This predetermined low temperature may vary depending on the setting; in some embodiments, the temperature may be 5 degrees Kelvin or less. In some embodiments, the non-quantum processing device 2028 (and various other components of the quantum computing device 2000) may not be cooled by the cooling apparatus 2024, and may instead operate at room temperature. The cooling apparatus 2024 may be, for example, a dilution refrigerator, a helium-3 refrigerator, or a liquid helium refrigerator.

In some embodiments, the quantum computing device 2000 may include a communication chip 2012 (e.g., one or more communication chips). For example, the communication chip 2012 may be configured for managing wireless communications for the transfer of data to and from the quantum computing device 2000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2012 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2012 may operate in accordance with other wireless protocols in other embodiments. The quantum computing device 2000 may include an antenna 2022 to facilitate wireless communications and/or to receive other wireless communications (such as AM or FM radio transmissions).

In some embodiments, the communication chip 2012 may manage wired communications, such as electrical, optical, or any other suitable communication protocols (e.g., the Ethernet). As noted above, the communication chip 2012 may include multiple communication chips. For instance, a first communication chip 2012 may be dedicated to shorter-range wireless communications such as Wi-Fi or Bluetooth, and a second communication chip 2012 may be dedicated to longer-range wireless communications such as GPS, EDGE, GPRS, CDMA, WiMAX, LTE, EV-DO, or others. In some embodiments, a first communication chip 2012 may be dedicated to wireless communications, and a second communication chip 2012 may be dedicated to wired communications.

The quantum computing device 2000 may include battery/power circuitry 2014. The battery/power circuitry 2014 may include one or more energy storage devices (e.g., batteries or capacitors) and/or circuitry for coupling components of the quantum computing device 2000 to an energy source separate from the quantum computing device 2000 (e.g., AC line power).

The quantum computing device 2000 may include a display device 2006 (or corresponding interface circuitry, as discussed above). The display device 2006 may include any visual indicators, such as a heads-up display, a computer monitor, a projector, a touchscreen display, a liquid crystal display (LCD), a light-emitting diode display, or a flat panel display, for example.

The quantum computing device 2000 may include an audio output device 2008 (or corresponding interface circuitry, as discussed above). The audio output device 2008 may include any device that generates an audible indicator, such as speakers, headsets, or earbuds, for example.

The quantum computing device 2000 may include an audio input device 2018 (or corresponding interface circuitry, as discussed above). The audio input device 2018 may include any device that generates a signal representative of a sound, such as microphones, microphone arrays, or digital instruments (e.g., instruments having a musical instrument digital interface (MIDI) output).

The quantum computing device 2000 may include a global positioning system (GPS) device 2016 (or corresponding interface circuitry, as discussed above). The GPS device 2016 may be in communication with a satellite-based system and may receive a location of the quantum computing device 2000, as known in the art.

The quantum computing device 2000 may include an other output device 2010 (or corresponding interface circuitry, as discussed above). Examples of the other output device 2010 may include an audio codec, a video codec, a printer, a wired or wireless transmitter for providing information to other devices, or an additional storage device.

The quantum computing device 2000 may include an other input device 2020 (or corresponding interface circuitry, as discussed above). Examples of the other input device 2020 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The quantum computing device 2000, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

### SELECTED EXAMPLES

Some Examples in accordance with various embodiments of the present disclosure are now described.

Example 1 provides a quantum circuit assembly that includes a quantum circuit component, the quantum circuit component including a plurality of qubits, and a control logic coupled to the quantum circuit component and configured to control operation of the quantum circuit component, where the quantum circuit component and the control logic are provided on a single die.

Example 2 provides the quantum circuit assembly according to Example 1, where the plurality of qubits include quantum dot qubits, the quantum circuit component further includes one or more plunger gates, and the control logic is configured to control voltage applied to the one or more plunger gates to control formation of quantum dots of the plurality of qubits.

Example 3 provides the quantum circuit assembly according to Example 2, where the plurality of qubits include quantum dot qubits, the quantum circuit component further includes one or more barrier gates, and the control logic is configured to control voltage applied to the one or more barrier gates to control a potential barrier between two adjacent plunger gates or between a plunger gate and an adjacent accumulation gate.

Example 4 provides the quantum circuit assembly according to Example 3, where the control logic is configured to initialize the quantum circuit component by setting the voltage applied to the one or more plunger gates and/or setting the voltage applied to the one or more barrier gates to ensure that initially no charge carriers are present in the quantum dots formed under the one or more plunger gates and then to ensure loading of a predefined number of charge carriers into each of the quantum dots.

Example 5 provides the quantum circuit assembly according to Example 1, where the plurality of qubits include quantum dot qubits, the quantum circuit component further includes one or more accumulation gates, and the control logic is configured to control voltage applied to the one or more accumulation gates to control a number of charge carriers in an area between an area where quantum dots are formed and a charge carrier reservoir.

Example 6 provides the quantum circuit assembly according to Example 1, where the plurality of qubits include quantum dot qubits, the quantum circuit component further includes a plurality of gates including one or more plunger gates, one or more barrier gates, and/or one or more accumulation gates, and the control logic is configured to control voltage applied to the plurality of gates.

Example 7 provides the quantum circuit assembly according to Example 1, further including a magnetic field generator, where the plurality of qubits include quantum dot qubits, the control logic is configured to control spins of charge carriers in quantum dots of the plurality of qubits by controlling a magnetic field generated by the magnetic field generator.

Example 8 provides the quantum circuit assembly according to Example 7, where the magnetic field generator includes a microwave transmission line or a magnet with one or more pulsed gates.

Example 9 provides the quantum circuit assembly according to Example 1, where the plurality of qubits include quantum dot qubits, the quantum circuit component further includes a plurality of gates including one or more plunger gates, one or more barrier gates, and/or one or more accumulation gates, and the control logic is configured to determine variations in gate voltages for forming different quantum dots.

Example 10 provides the quantum circuit assembly according to Example 9, where the control logic is configured to characterize formation of each quantum dot and to determine the variations based on an outcome of the characterization.

Example 11 provides the quantum circuit assembly according to Example 1, where the plurality of qubits include superconducting qubits, the quantum circuit component further includes one or more flux bias lines for the plurality of qubits, and the control logic is configured to control current in the one or more flux bias lines.

Example 12 provides the quantum circuit assembly according to Example 1, where the plurality of qubits include superconducting qubits, the quantum circuit component further includes one or more microwave lines for the plurality of qubits, and the control logic is configured to detect current in the one or more microwave lines and to control the operation of the quantum circuit component based on the detected current.

Example 13 provides the quantum circuit assembly according to Example 12, where the control logic is further configured to control the current in the one or more microwave lines.

Example 14 provides the quantum circuit assembly according to Example 13, where the control logic is configured to switch operation of the one or more microwave lines between controlling the current in the one or more microwave lines to control states of the plurality of qubits and detecting the current in the one or more microwave lines to detect the states of the plurality of qubits.

Example 15 provides the quantum circuit assembly according to Example 1, where the plurality of qubits include superconducting qubits, the quantum circuit component further includes one or more drive lines for the plurality of qubits, and the control logic is configured to control current in the one or more drive lines.

Example 16 provides the quantum circuit assembly according to Example 15, where the control logic is configured to control the current in the one or more drive lines by ensuring provision of one or more pulses of the current at a frequency of the plurality of qubits.

Example 17 provides the quantum circuit assembly according to Example 16, where the control logic is configured to control a duration of the one or more pulses.

Example 18 provides a quantum computing device including a quantum circuit assembly and a memory device. The quantum circuit assembly includes a quantum circuit component including a plurality of qubits and a control logic configured to control operation of the quantum circuit component, where the quantum circuit component and the control logic are provided on a single die. The memory device configured to store data generated and/or used by the control logic during the operation of the quantum circuit component.

Example 19 provides the quantum computing device according to Example 18, further including a cooling apparatus configured to maintain a temperature of the quantum circuit assembly below 5 degrees Kelvin.

Example 20 provides the quantum computing device according to Examples 18 or 19, where the memory device is configured to store instructions for a quantum computing algorithm to be executed by the control logic.

Example 21 provides a method for forming a quantum circuit assembly. The method includes providing a first mask over one or more portions of a substrate on which a quantum circuit component including a plurality of qubits is to be formed; carrying out a first fabrication process on the substrate with the first mask, the first fabrication process forming at least a portion of a control logic on one or more portions of the substrate on which the control logic is to be formed; removing the first mask; and carrying out a second fabrication process on the substrate, the second fabrication process forming at least a portion of the quantum circuit component on the substrate.

Example 22 provides the method according to Example 21, further including providing a second mask over the one or more portions of the substrate on which the control logic is to be formed, where the second fabrication process is carried out on the substrate with the second mask.

Example 23 provides the method according to Example 21, where the first mask includes a layer of an oxide or a nitride material.

Example 24 provides the method according to Example 21, further including interconnecting the control logic and the quantum circuit component.

Example 25 provides the method according to any one of Examples 21-24, further including dicing the substrate to form a die including the quantum circuit component and the control logic.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

1. A quantum circuit assembly, comprising:
a quantum circuit component, the quantum circuit component comprising a plurality of qubits; and
a control logic coupled to the quantum circuit component and configured to control operation of the quantum circuit component,
wherein the quantum circuit component and the control logic are provided on a single die.

2. The quantum circuit assembly according to claim 1, wherein:
the plurality of qubits comprise quantum dot qubits,
the quantum circuit component further comprises one or more plunger gates, and
the control logic is configured to control voltage applied to the one or more plunger gates to control formation of quantum dots of the plurality of qubits.

3. The quantum circuit assembly according to claim 2, wherein:
the plurality of qubits comprise quantum dot qubits,
the quantum circuit component further comprises one or more barrier gates, and
the control logic is configured to control voltage applied to the one or more barrier gates to control a potential barrier between two adjacent plunger gates or between a plunger gate and an adjacent accumulation gate.

4. The quantum circuit assembly according to claim 3, wherein the control logic is configured to initialize the quantum circuit component by setting the voltage applied to the one or more plunger gates and/or setting the voltage applied to the one or more barrier gates to ensure that initially no charge carriers are present in the quantum dots formed under the one or more plunger gates and then to ensure loading of a predefined number of charge carriers into each of the quantum dots.

5. The quantum circuit assembly according to claim 1, wherein:
the plurality of qubits comprise quantum dot qubits,
the quantum circuit component further comprises one or more accumulation gates, and
the control logic is configured to control voltage applied to the one or more accumulation gates to control a number of charge carriers in an area between an area where quantum dots are formed and a charge carrier reservoir.

6. The quantum circuit assembly according to claim 1, wherein:
the plurality of qubits comprise quantum dot qubits,
the quantum circuit component further comprises a plurality of gates comprising one or more plunger gates, one or more barrier gates, and/or one or more accumulation gates, and
the control logic is configured to control voltage applied to the plurality of gates.

7. The quantum circuit assembly according to claim 1, further comprising a magnetic field generator, wherein:
the plurality of qubits comprise quantum dot qubits,
the control logic is configured to control spins of charge carriers in quantum dots of the plurality of qubits by controlling a magnetic field generated by the magnetic field generator.

8. The quantum circuit assembly according to claim 7, wherein the magnetic field generator comprises a microwave transmission line or a magnet with one or more pulsed gates.

9. The quantum circuit assembly according to claim 1, wherein:
the plurality of qubits comprise quantum dot qubits,
the quantum circuit component further comprises a plurality of gates comprising one or more plunger gates, one or more barrier gates, and/or one or more accumulation gates, and
the control logic is configured to determine variations in gate voltages for forming different quantum dots.

10. The quantum circuit assembly according to claim 9, wherein the control logic is configured to characterize formation of each quantum dot and to determine the variations based on an outcome of the characterization.

11. The quantum circuit assembly according to claim 1, wherein:
the plurality of qubits comprise superconducting qubits,
the quantum circuit component further comprises one or more flux bias lines for the plurality of qubits, and
the control logic is configured to control current in the one or more flux bias lines.

12. The quantum circuit assembly according to claim 1, wherein:
the plurality of qubits comprise superconducting qubits,
the quantum circuit component further comprises one or more microwave lines for the plurality of qubits, and
the control logic is configured to detect current in the one or more microwave lines and to control the operation of the quantum circuit component based on the detected current.

13. (canceled)

14. (canceled)

15. The quantum circuit assembly according to claim 1, wherein:
the plurality of qubits comprise superconducting qubits,
the quantum circuit component further comprises one or more drive lines for the plurality of qubits, and
the control logic is configured to control current in the one or more drive lines.

16. The quantum circuit assembly according to claim 15, wherein the control logic is configured to control the current in the one or more drive lines by ensuring provision of one or more pulses of the current at a frequency of the plurality of qubits, and
wherein the control logic is configured to control a duration of the one or more pulses.

17. (canceled)

18. A quantum computing device, comprising:
a quantum circuit assembly comprising a quantum circuit component comprising a plurality of qubits and a control logic configured to control operation of the quantum circuit component, wherein the quantum circuit component and the control logic are provided on a single die; and
a memory device configured to store data generated and/or used by the control logic during the operation of the quantum circuit component.

19. The quantum computing device according to claim 18, further comprising a cooling apparatus configured to maintain a temperature of the quantum circuit assembly below 5 degrees Kelvin.

20. (canceled)

21. A method for forming a quantum circuit assembly, the method comprising:
providing a first mask over one or more portions of a substrate on which a quantum circuit component comprising a plurality of qubits is to be formed;
carrying out a first fabrication process on the substrate with the first mask, the first fabrication process forming at least a portion of a control logic on one or more portions of the substrate on which the control logic is to be formed;
removing the first mask; and
carrying out a second fabrication process on the substrate, the second fabrication process forming at least a portion of the quantum circuit component on the substrate.

22. The method according to claim 21, further comprising providing a second mask over the one or more portions of the substrate on which the control logic is to be formed, wherein the second fabrication process is carried out on the substrate with the second mask.

23. The method according to claim 21, wherein the first mask comprises a layer of an oxide or a nitride material.

24. The method according to claim 21, further comprising interconnecting the control logic and the quantum circuit component.

25. (canceled)
